(19) United States
(12) Patent Application Publication
(10) Pub. No.: US 2009/0051461 A1
(43) Pub. Date: Feb. 26, 2009

(54) OUTPUT POWER DETECTING SYSTEM WITH A DIRECTIONAL COUPLER

(75) Inventors: CHUNG-ER HUANG, TAIPEI (TW); HUANG-CHAN CHIEN, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: AZUREWAVE TECHNOLOGIES, INC., TAIPEI (TW)

(21) Appl. No.: 11/842,529

(22) Filed: Aug. 21, 2007

(51) Int. Cl. H01P 5/18; G01R 21/00

(52) U.S. Cl. 333/109; 330/2

(57) ABSTRACT

A output power detecting system with a directional coupler has a directional coupler at the output terminal of the output power detecting system. The directional coupler includes a main line, a first sub line, and a second sub line. The output of the power amplifying unit is fully coupled to a power detecting unit via the coupling between the main line and the first sub line, and the external noise is coupled to the ground via the coupling between the first sub line and the second sub line. Therefore, the power detecting unit accurately detects the output power of the output power detecting system.

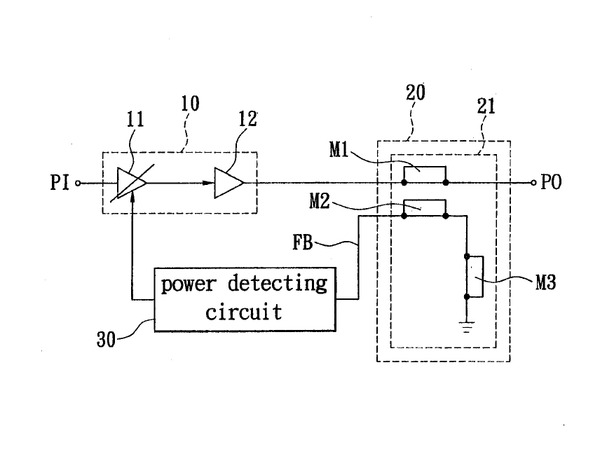

### BACKGROUND OF THE INVENTION

1. Field of the Invention

The present invention relates to a high frequency system. In particular, this invention relates to an output power detecting system with a directional coupler.

2. Description of the Related Art

Because the output power of the power amplifier in a high frequency system will be changed due to the variation of temperature and the matching impedance at the output terminal, the designer usually adds a power detecting circuit in the high frequency system to detect the variation of the output power of the power amplifier. Thereby, the high frequency system is controlled to adjust the output power of the power amplifier so that the high frequency system stably operates.

In a modulated product, each of the elements is usually manufactured on a printed circuit board (PCB). Then, the output power of the modulated product is coupled to the power detecting circuit by a capacitor or resistor coupling method. Therefore, the power detecting circuit uses the received feedback signal to judge the output power.

However, because the operational environment of the printed circuit board in the modulated product usually is different from the testing environment, the impedance will be not matched. Because the impedance is not matched, a lot of reactions that are not belonging to the design targets generate. Furthermore, the external noise is easily coupled to the power detecting circuit. Therefore, the detecting result of the power detecting circuit is inaccurate, and the high frequency system is affected.

### SUMMARY OF THE INVENTION

One particular aspect of the present invention is to provide an output power detecting system with a directional coupler. At the output terminal of the output power detecting system, a directional coupler is installed. Therefore, the output power of the power amplifying unit is fully coupled to a power detecting unit, and the detecting result of the power detecting unit will not be interfered by the external noise. The power detecting unit accurately detects the output power of the output power detecting system.

The output power detecting system includes a power amplifying unit, an impedance matching circuit, and a power detecting circuit. The impedance matching circuit includes a directional coupler located at the output terminal of the output power detecting system.

The directional coupler includes a main line, a first sub line, and a second sub line. The first end of the main line is connected with the output terminal of the output power detecting system. The second end of the main line is connected with the output terminal of the power amplifying unit. The first end of the first sub line is connected with the power detecting circuit. The second end of the first sub line is connected with the first end of the second sub line. The second end of the second sub line is connected to ground.

When the output power detecting system transmits a high frequency signal, the first end of the main line is coupled to the first end of the first sub line, and first end of the second sub line is coupled to the output terminal of the output power detecting system.

Therefore, the power detecting circuit obtains the feedback signal without noise from the output terminal of the output power detecting system to judge the output power of the output power detecting system.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

The FIGURE is a schematic diagram of the output power detecting system of the present invention.

### DETAILED DESCRIPTION OF THE PREFERRED EMBODIMENTS

The present invention is a modulated design and is suitable for a high frequency system. Especially, it is suitable for an integrated passive component (IPC) with a high dielectric constant, or an integrated passive device (IPC) with a high dielectric constant. The dielectric constant of the substrate for the integrated passive component or the integrated passive device is high than the dielectric constant of the BT or FR4. Therefore, the present invention can be manufactured onto the substrate of the integrated passive component or the integrated passive device.

Reference is made to the FIGURE, which shows a schematic diagram of the output power detecting system of the present invention. The output power detecting system includes a power amplifying unit 10, an impedance matching circuit 20, and a power detecting circuit 30.

The power amplifying unit 10 receives a high frequency signal from an input terminal PI, and amplifies the high frequency signal. The power amplifying unit 10 includes a variable gain amplifier 11, and a power amplifier 12. The variable gain amplifier 11 controls the output of the power amplifying unit 10 according to a control signal, and the power amplifier 12 amplifies the power of the high frequency signal according to the output of the variable gain amplifier 11.

The impedance matching circuit 20 transmits the high frequency signal from the input terminal PI to an output terminal PO, and prevents the spurious effect from occurring. The impedance matching circuit 20 includes a directional coupler 21. The directional coupler 21 is located at one linking point on an output line, and the directional coupler 21 includes a main line M1, a first sub line M2, and a second sub line M2.

The main line M1 is a transmission line, and the first end of the main line M1 is connected with the output terminal PO. The second end of the main line M1 is connected with the output terminal of the power amplifier 12 of the power amplifying unit 10. The first sub line M2 is parallel to the main line M1, and the first end of the first sub line M2 is connected with the power detecting circuit 30. The second end of the first sub line M2 is connected with the first end of the second sub line M3. The second end of the second sub line M3 is connected to ground.

When the amplified high frequency signal is outputted from the output terminal PO, the second end of the main line M1 is coupled to the first end of the first sub line M2, and first end of the second sub line M3 is coupled to the output terminal PO. Thereby, the output power detecting system utilizing the coupling between the main line M1 and the first sub line M2 to form a detecting circuit loop between the power amplifying unit 10 and the power detecting circuit 30.

In order to prevent the reflection wave and noise from feed backing the power detecting circuit 30 via the directional coupler 21 to generate an inaccurate detecting result, the lengths of the main line M1 and the first sub line M2 in the directional coupler 21 is a multiple of ¼ wavelength.

Therefore, by using the detecting circuit loop, the high frequency signal that is transmitted to the directional coupler 21 forms a feedback signal FB and is transmitted to the power detecting circuit 30. The high frequency signal will not generate a reflection wave in the directional coupler 21 to affect the output of the power amplifying unit 10. The power detecting circuit 30 uses the feedback signal FB to judge the power of the high frequency signal outputted from the output terminal PO, and generates a corresponding control signal to the variable gain amplifier 11 to control the variable gain amplifier 11 and adjust the output.

At the same time, when the high frequency signal is outputted, noise may be coupled to the output power detecting system via the output terminal PO. However, because the output terminal PO and the first sub line M2 form an open circuit, the multiple connecting mismatching effect and the noise at the output terminal PO are not coupled to the power detecting circuit 30 via the first sub line M2. On the contrary, the noise is coupled to ground by using the coupling between the second sub line M3 and the output terminal PO.

Therefore, the power detecting circuit uses the feedback signal without the noise to accurate detect the output power at the output terminal PO. Furthermore, because the manufacturing process of the IPC or IPD substrate is more stable than the manufacturing process of the BT or LTCC substrate, and the stray effect is small in an integrated design, the present invention is more stable and reliable that an SMT-typed power detecting circuit loop.

One characteristic of the present invention is that the output power detecting system is located on a substrate of the integrated passive component (IPC) or the integrated passive device (IPC) with a high dielectric constant.

Another characteristic of the present invention is that the elements are manufactured on a substrate of the integrated passive component (IPC) or the integrated passive device (IPC) with a high dielectric constant to enhance the impedance matching and stability at the output terminal.

A further characteristic of the present invention is that noise is directly coupled to ground.

A further characteristic of the present invention is that the power detecting circuit uses the noiseless feedback to detect the power of the output terminal.

A further characteristic of the present invention is that the length of the directional coupler is a multiple of ¼ wavelength.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. An output power detecting system with a directional coupler, comprising:
an input terminal for receiving a high frequency signal;
a power amplifying unit connected with the input terminal for amplifying the high frequency signal;
an output terminal connected with the power amplifying unit for outputting the amplified high frequency signal;
a directional coupler located at a linking point on an output line, wherein the linking point is connected with the power amplifying unit via the output terminal, the directional coupler includes a main line, a first sub line, and a second sub line, the first sub line is parallel to the main line, and the second sub line is vertically connected with the first sub line; and
a power detecting circuit connected with the power amplifying unit and the output terminal, wherein the power detecting circuit uses a feedback provided by the directional coupler to detect an out power of the power amplifying unit, and generates a control signal to control the output of the power amplifying unit;
wherein, when the high frequency signal is outputted, a first end of the main line is coupled to the output terminal, a second end of the main line is coupled to the power amplifying unit and a first end of the first sub line, a second end of the second sub line is coupled to the output terminal, and a second end of the second sub line is connected to a ground;
thereby, the power detecting circuit utilizes the coupling between the main line and the first sub line to receiving the feedback signal, and the noise received by the output terminal is transmitted to the ground via the coupling between the output terminal and the second sub line.

2. The output power detecting system with a directional coupler in claim 1, wherein the length of the main line and the first sub line is a multiple of 1/4 wavelength.

3. The output power detecting system with a directional coupler in claim 1, wherein the power amplifying unit comprises a variable gain amplifier connected with the input terminal and a power amplifier connected with the variable gain amplifier and the output terminal, and the variable gain amplifier control the output of the power amplifier according to the feedback signal.

4. The output power detecting system with a directional coupler in claim 1, wherein the output power detecting system is manufactured on an integrated passive component.

5. The output power detecting system with a directional coupler in claim 1, wherein the output power detecting system is manufactured on an integrated passive device.

6. The output power detecting system with a directional coupler in claim 1, wherein the main line is a transmission line and is located in an impedance matching circuit.

7. A directional coupler, located in an output power detecting system for separating noise and coupling a feedback signal to the output power detecting system so that the output power detecting system accurately detects an output power of a power amplifying unit, comprising:
a main line, wherein a first end of the main line is connected with an output terminal of the output power detecting system, and a second end of the main line is connected with the power amplifying unit;
a first sub line being parallel to the main line, wherein a first end of the first sub line is connected with the power amplifying unit; and
a second sub line, wherein a first end of the second sub line is vertically connected with a second end of the first sub line, and a second end of the second sub line is connected with a ground;
wherein the directional coupler is located at a linking point on an output line in the output power detecting system, and the linking point is connected with the power amplifying unit via the output terminal;
wherein, the directional coupler is a signal, the first end of the first sub line is coupled to the second end of the main line, and the first end of the second sub line is coupled to the output terminal;
thereby, the power detecting circuit utilizes the coupling between the main line and the first sub line to receiving the feedback signal, and the noise received by the output terminal is transmitted to the ground via the coupling between the output terminal and the second sub line.

8. The directional coupler in claim 7, wherein the length of the main line and the first sub line is a multiple of ¼ wavelength.

9. The directional coupler in claim 7, wherein the output power detecting system is manufactured on an integrated passive component.

10. The directional coupler in claim 7, wherein the output power detecting system is manufactured on an integrated passive device.

11. The directional coupler in claim 7, wherein the main line is a transmission line and is located in an impedance matching circuit of the output power detecting system.
